(19) United States
(12) Patent Application Publication
(10) Pub. No.: US 2021/0092876 A1
(43) Pub. Date: Mar. 25, 2021

(54) LOCAL AIR CONDITIONER AND METHOD FOR MANUFACTURING LOCAL AIR CONDITIONER SYSTEM

(71) Applicant: NEC Corporation, Minato-ku, Tokyo (JP)

(72) Inventors: Koichi TODOROKI, Tokyo (JP); Minoru YOSHIKAWA, Tokyo (JP); Kunihiko ISHIHARA, Tokyo (JP); Masaki CHIBA, Tokyo (JP)

(73) Assignee: NEC Corporation, Minato-ku, Tokyo (JP)

(21) Appl. No.: 16/772,447

(22) PCT Filed: Dec. 17, 2018
(86) PCT No.: PCT/JP2018/046271

§ 371 Date: Jun. 12, 2020

(30) Foreign Application Priority Data
Dec. 22, 2017 (JP) 2017-245655

(51) Int. Cl. H05K 7/20; F28F 9/02

(52) U.S. Cl. CPC H05K 7/20745; F24F 13/30; F28F 9/02

(57) ABSTRACT

The present invention provides a local air conditioner. In a local air conditioner system provided with a plurality of local air conditioners, an increase in the number of local air conditioners is problematic. Thus, the local air conditioner of the present invention comprising: a heat exchanger; a first main flow pipe; a second main flow pipe; a first branch pipe that connects the heat exchanger and the first main flow pipe; and a second branch pipe that connects the heat exchanger and the second main flow pipe, wherein the first main flow pipe is provided with a first connection structure on both end portions and the second main flow pipe is provided with a second connection structure on both end portions.

### TECHNICAL FIELD

The present invention relates to a local air conditioner and a method for manufacturing a local air conditioner system, and particularly to a local air conditioner and a method for manufacturing a local air conditioner system to be arranged near a storage rack for electronic equipment and the like.

### BACKGROUND ART

In a data center that houses many server racks storing electronic equipment such as a server device, a cooling system in which a plurality of local air conditioners are arranged side by side above the server racks is used. PTL 1 describes one example of such a cooling system using the local air conditioner.

The cooling system described in PTL 1 includes a local air conditioner as a cooling device and a refrigerant device. For example, server racks being cooling targets form a server rack row with four racks, and the four server racks each face each of other four server racks. Four local air conditioners are arranged above the server racks, each facing each of other four local air conditioners similarly to the server racks. These local air conditioners perform heat exchange between a liquid refrigerant conveyed from a refrigerant device through a refrigerant pipe and air (warm air) taken from an air inlet. The liquid refrigerant heated by heat exchange becomes a gas refrigerant and is returned to the refrigerant device through the refrigerant pipe.

The refrigerant device is configured to convey the liquid refrigerant to the local air conditioner through the refrigerant pipe, collect the refrigerant that becomes the gas refrigerant by heat absorption through the refrigerant pipe, change the gas refrigerant into the liquid refrigerant by cooling, and then convey again the liquid refrigerant through the refrigerant pipe.

Further, PTL 2 discloses a local air conditioning system in which one cooling/heating source unit is provided for a plurality of local cooling devices. In the local air conditioning system, supply/collection of a refrigerant is performed via refrigerant piping (refrigerant going piping and refrigerant return piping) common to the plurality of local cooling devices. One or a plurality of piping headers are provided in the middle of the refrigerant piping. The piping header is used for connecting a plurality of branch pipes to main piping. The local air conditioning system described in PTL 2 is configured to arrange distributively the piping headers on the refrigerant piping, and connect the piping header and the local cooling device by flexible piping.

### CITATION LIST

### Patent Literature

[PTL 1] Japanese Unexamined Patent Application Publication No. 2013-221634

[PTL 2] Japanese Unexamined Patent Application Publication No. 2011-257117

### SUMMARY OF INVENTION

### Technical Problem

As described above, the cooling system described in PTL 1 has a piping configuration in which main liquid refrigerant piping for supplying the liquid refrigerant and main vapor refrigerant piping through which a vapor refrigerant evaporated by absorbing exhaust heat is returned are provided, and a liquid pipe and a vapor pipe of the local air conditioner are connected to the main piping.

However, in such a piping configuration, construction to extend the main piping is required when a new local air conditioner is added. A stainless steel pipe (SUS pipe) and a copper pipe are mainly used for the main piping, and thus extension of the main piping requires a specialized construction technique and equipment. Therefore, there is a problem that a cost of installing an additional local air conditioner is high. Further, it is difficult to additionally install a local air conditioner while maintaining safety of a running server.

As described above, the local air conditioning system described in PTL 2 is configured to include a plurality of piping headers and connect the piping headers and a plurality of local cooling devices by the flexible piping. Thus, the configuration enables the local cooling device to be moved and be additionally installed easily without performing machining.

However, even when such a piping header is used, the problem of difficulty in installation work for additionally installing the local cooling device cannot be solved. A reason for this is that, when the local cooling device is additionally installed beyond the number of joints included in the piping header, it is necessary to install an additional piping header, however, it is difficult to construct for inserting the piping header in the middle of the refrigerant piping.

Thus, there is a problem of difficulty in installing an additional local air conditioner in the local air conditioner system including a plurality of local air conditioners.

An object of the present invention is to provide a local air conditioner and a method for manufacturing a local air conditioner system that solve the above-described issue of difficulty in installing an additional local air conditioner in a local air conditioner system including a plurality of local air conditioners.

### Solution to Problem

A local air conditioner according to the present invention includes: a heat exchanger; a first main flow pipe; a second main flow pipe; a first branch flow pipe that connects the heat exchanger and the first main flow pipe; and a second branch flow pipe that connects the heat exchanger and the second main flow pipe, wherein the first main flow pipe includes a first connection structure on each of both end portions and the second main flow pipe includes a second connection structure on each of both end portions.

A method for manufacturing a local air conditioner system according to the present invention includes providing a first heat exchanger, a first main flow pipe, a second main flow pipe, a first branch flow pipe that connects the first heat exchanger and the first main flow pipe, and a second branch flow pipe that connects the first heat exchanger and the second main flow pipe, wherein the first main flow pipe includes a first connection structure on each of both end portions, and the second main flow pipe forms a first local air conditioner including a second connection structure on each of both end portions, and providing a second heat exchanger, a third main flow pipe, a fourth main flow pipe, a third branch flow pipe that connects the second heat exchanger and the third main flow pipe, and a fourth branch flow pipe that connects the second heat exchanger and the fourth main flow pipe, wherein the third main flow pipe includes a third connection structure on each of both end portions, and the fourth main flow pipe forms a second local air conditioner including a fourth connection structure on each of both end portions, connects the first connection structure and the third connection structure, and connects the second connection structure and the fourth connection structure.

### Advantageous Effects of Invention

The local air conditioner and the method for manufacturing the local air conditioner system according to the present invention are able to easily install an additional local air conditioner in the local air conditioner system including a plurality of local air conditioners.

### BRIEF DESCRIPTION OF DRAWINGS

FIG. 1 is a schematic diagram schematically illustrating a configuration of a local air conditioner according to a first example embodiment of the present invention.

FIG. 2 is a schematic diagram schematically illustrating a configuration of a local air conditioner system according to the first example embodiment of the present invention.

FIG. 3 is a schematic diagram schematically illustrating another configuration of the local air conditioner according to the first example embodiment of the present invention.

FIG. 4 is a schematic diagram schematically illustrating another configuration of the local air conditioner system according to the first example embodiment of the present invention.

FIG. 5 is a schematic diagram schematically illustrating still another configuration of the local air conditioner according to the first example embodiment of the present invention.

FIG. 6 is a schematic diagram schematically illustrating still another configuration of the local air conditioner system according to the first example embodiment of the present invention.

FIG. 7 is a schematic diagram schematically illustrating still another configuration of the local air conditioner system according to the first example embodiment of the present invention.

FIG. 8 is a schematic diagram schematically illustrating still another configuration of the local air conditioner system according to the first example embodiment of the present invention.

FIG. 9 is a schematic diagram schematically illustrating still another configuration of the local air conditioner system according to the first example embodiment of the present invention.

FIG. 10 is a schematic diagram schematically illustrating a configuration of a local air conditioner system according to a second example embodiment of the present invention.

FIG. 11 is a schematic diagram schematically illustrating another configuration of the local air conditioner system according to the second example embodiment of the present invention.

### EXAMPLE EMBODIMENT

In the following, example embodiments of the present invention will be described with reference to the drawings.

### First Example Embodiment

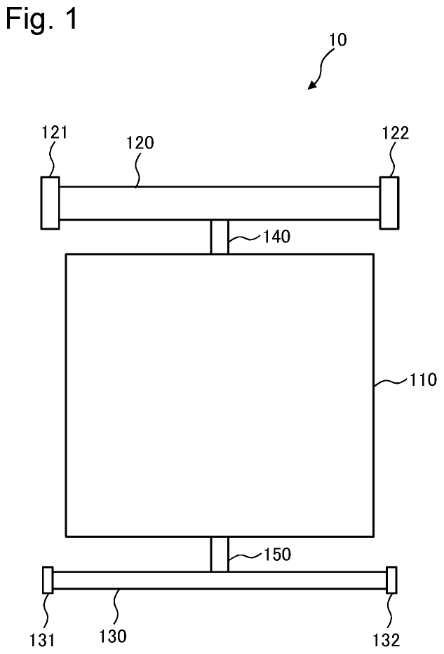

FIG. 1 is a schematic diagram schematically illustrating a configuration of a local air conditioner 10 according to a first example embodiment of the present invention.

The local air conditioner 10 according to the present example embodiment includes a heat exchanger 110, a first main flow pipe 120, a second main flow pipe 130, a first branch flow pipe 140 that connects the heat exchanger 110 and the first main flow pipe 120, and a second branch flow pipe 150 that connects the heat exchanger 110 and the second main flow pipe 130. The first main flow pipe 120 includes first connection structures 121 and 122 on both end portions, and the second main flow pipe 130 includes second connection structures 131 and 132 on both end portions.

Herein, the first connection structures 121 and 122 and the second connection structures 131 and 132 each can be configured to include any of a sanitary flange and a normal flange. The configuration is not limited to the above, and the first connection structures 121 and 122 and the second connection structures 131 and 132 may have a configuration using a coupler or a cap nut, or a configuration having a flare structure.

As described above, the local air conditioner 10 according to the present example embodiment includes the heat exchanger 110, the first main flow pipe 120 and the second main flow pipe 130, and the first branch flow pipe 140 and the second branch flow pipe 150. The local air conditioner 10 according to the present example embodiment is configured in such a way that the first main flow pipe 120 and the second main flow pipe 130 include the first connection structures 121 and 122 and the second connection structures 131 and 132, respectively. Therefore, when the local air conditioner 10 is additionally installed, the local air conditioners 10 can be connected to each other by using the first connection structures 121 and 122 and the second connection structures 131 and 132. Thus, there is no need to process metallic pipes constituting the first main flow pipe 120 and the second main flow pipe 130. Accordingly, an extension work becomes easy, resulting in reducing a construction cost for additionally installing the local air conditioner 10.

In other words, the local air conditioner 10 according to the present example embodiment is able to easily install an additional local air conditioner in the local air conditioner system including a plurality of local air conditioners.

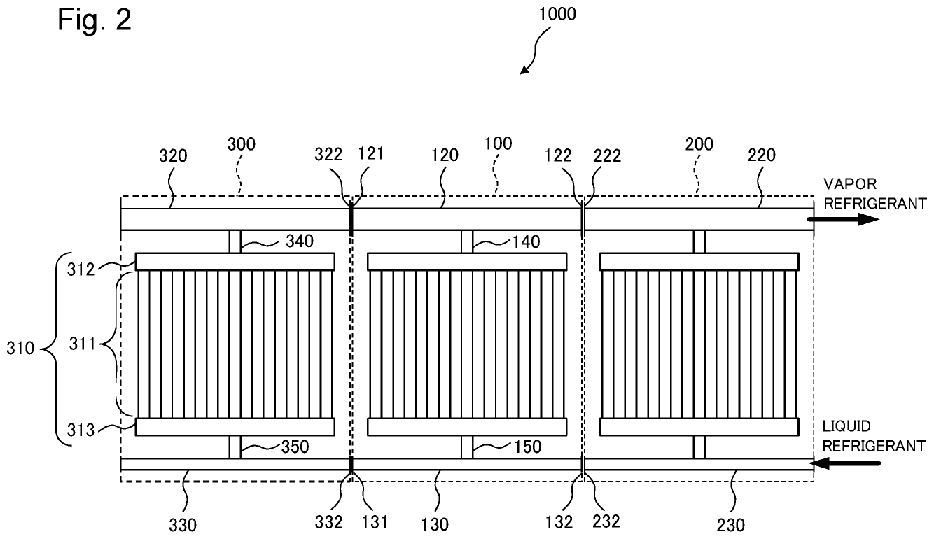

FIG. 2 schematically illustrates a configuration of a local air conditioner system 1000 including a plurality of local air conditioners according to the present example embodiment. In FIG. 2, a case where the local air conditioner system 1000 includes three local air conditioners is illustrated, however the number of local air conditioners is not limited to this.

The local air conditioner system 1000 according to the present example embodiment includes at least a first local air conditioner 100 and a second local air conditioner 200. Then, the first connection structure 122 included in the first local air conditioner 100 and a first connection structure 222 included in the second local air conditioner 200 are connected. Further, the second connection structure 132 included in the first local air conditioner 100 and a second connection structure 232 included in the second local air conditioner 200 are connected.

Herein, the first main flow pipe 120 and first main flow pipes 220 and 320 can be set as vapor piping through which a vapor-phase refrigerant (a vapor refrigerant) mainly flows. The first main flow pipes 120, 220 and 320 are connected by the first connection structures 122 and 222 (121 and 322), and thus main vapor piping is formed.

On the other hand, the second main flow pipe 130 and second main flow pipes 230 and 330 can be set as liquid piping through which a liquid-phase refrigerant (a liquid refrigerant) mainly flows. The second main flow pipes 130, 230, and 330 are connected by the second connection structures 132 and 232 (131 and 332), and thus main liquid piping is formed.

In this way, the first main flow pipe 120 can be set as a vapor main flow pipe having the first connection structure 121 at one end where the vapor refrigerant flows in and the first connection structure 122 at the other end where the vapor refrigerant flows out. The second main flow pipe 130 can be set as a liquid main flow pipe having the second connection structure 132 at one end where the liquid refrigerant flows in and the second connection structure 131 at the other end where the liquid refrigerant flows out.

In this case, the liquid refrigerant flows from the local air conditioner (second local air conditioner 200) adjacent (right side in the example of FIG. 2) to the first local air conditioner 100 into the liquid main flow pipe (second main flow pipe 130), and a part of the liquid refrigerant flows into the heat exchanger 110 through the liquid branch flow pipe (second branch flow pipe 150). The remaining liquid refrigerant flows into the adjacent (left side in the example of FIG. 2) local air conditioner (third local air conditioner 300). The liquid refrigerant that receives heat in the heat exchanger 110 evaporates and flows into the vapor main flow pipe (first main flow pipe 120) through the vapor branch flow pipe (first branch flow pipe 140). In the vapor main flow pipe (first main flow pipe 120), the vapor-phase refrigerant flowing in from the adjacent (left side in the example of FIG. 2) local air conditioner (third local air conditioner 300) and the vapor-phase refrigerant flowing in through the vapor branch flow pipe (first branch flow pipe 140) join together, and then flow into the adjacent (right side in the example of FIG. 2) local air conditioner (second local air conditioner 200).

As a heat exchanger 310 included in the third local air conditioner 300 illustrated in FIG. 2, the heat exchanger can be configured to include a heat exchange unit 311, a first header unit 312 to be connected to the heat exchange unit 311, and a second header unit 313 to be connected to the heat exchange unit 311. The first header unit 312 is located on one side and the second header unit 313 is located on the other side across the heat exchange unit 311. Further, a first branch flow pipe 340 can be configured to be connected to the first header unit 312 and a second branch flow pipe 350 can be configured to be connected to the second header unit 313.

As the heat exchanger 310, typically, a fin tube type heat exchanger that allows a liquid medium to flow in a heat transfer tube (tube) and exposes gas to a heat transfer plate (fin) to perform heat exchange can be used.

Herein, the local air conditioner can be configured in such a way that the first branch flow pipe 340 is connected to the first header unit 312 at the center of the first header unit 312, as the third local air conditioner 300 illustrated in FIG. 2. Similarly, it can be configured that the second branch flow pipe 350 is connected to the second header unit 313 at the center of the second header unit 313.

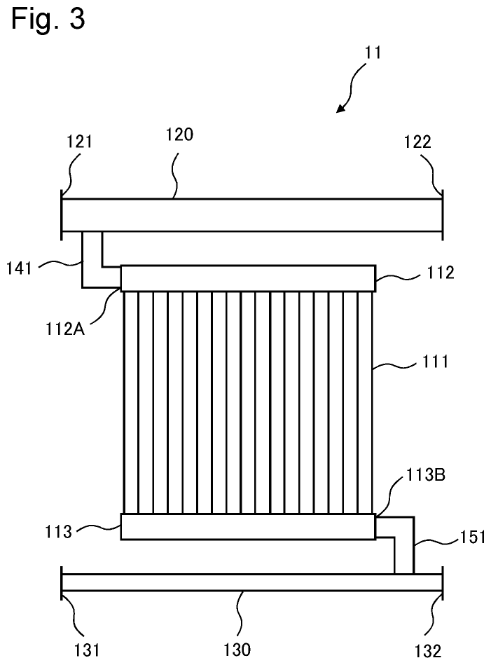

The configuration is not limited to this and can be a configuration as a local air conditioner 11 illustrated in FIG. 3. In the local air conditioner 11, a first branch flow pipe 141 is connected to a first header unit 112 at a first end portion 112A of the first header unit 112, and a second branch flow pipe 151 is connected to a second header unit 113 at a second end portion 113B of the second header unit 113. The first end portion 112A and the second end portion 113B can be configured to be located on different sides of side surfaces of a heat exchange unit 111. In other words, it can be configured in such a way that the first branch flow pipe 141 (vapor branch flow pipe) and the second branch flow pipe 151 (liquid branch flow pipe) are located diagonally to the heat exchange unit 111.

Such a configuration enables the refrigerant flowing in the heat exchange unit 111 to be more equal. As a result, heat removal performance of the local air conditioner 11 can be increased.

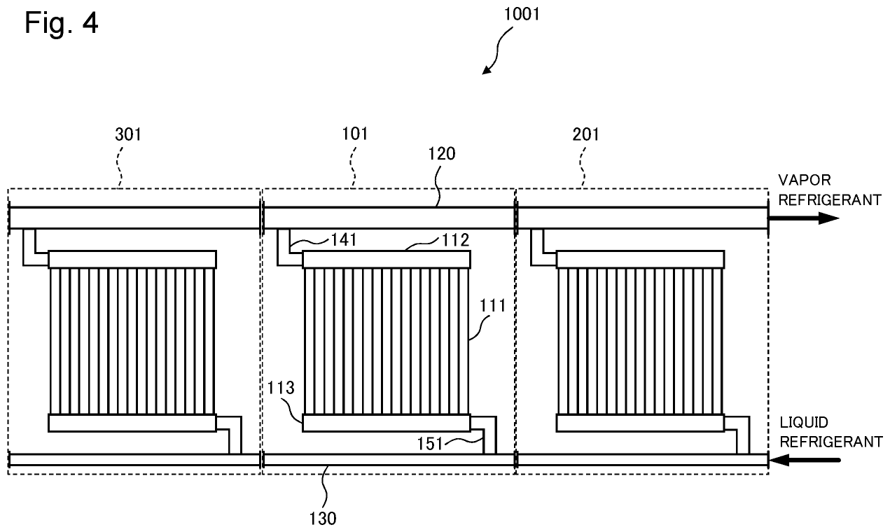

FIG. 4 illustrates a configuration of a local air conditioner system 1001 using a first local air conditioner 101, a second local air conditioner 201, and a third local air conditioner 301, each having the same configuration as the local air conditioner 11.

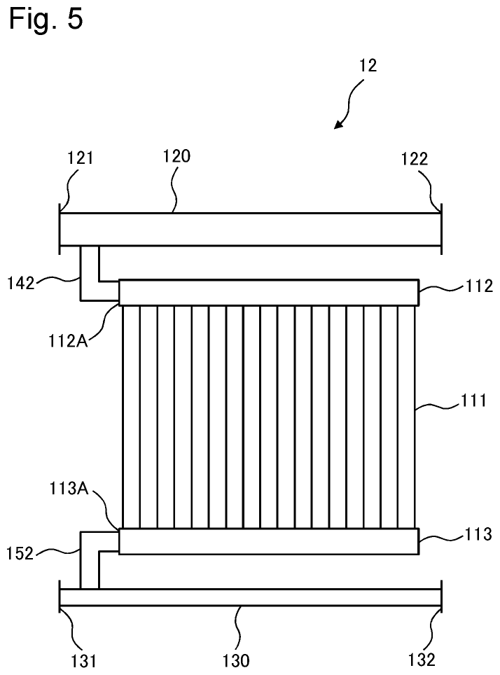

Further, it may be configured in such a way that a first branch flow pipe 142 (vapor branch flow pipe) and a second branch flow pipe 152 (liquid branch flow pipe) are connected on the same side of the heat exchange unit 111 as a local air conditioner 12 illustrated in FIG. 5. Specifically, in the local air conditioner 12, the first branch flow pipe 142 is connected to the first header unit 112 at the first end portion 112A of the first header unit 112, and the second branch flow pipe 152 is connected to the second header unit 113 at a second end portion 113A of the second header unit 113. The first end portion 112A and the second end portion 113A can be configured to be located on the same side of the side surface of the heat exchange unit 111.

Such a configuration enables increasing an area of the heat exchange unit 111 by the first branch flow pipe 142 and the second branch flow pipe 152 being arranged on the same side of the heat exchange unit 111. As a result, heat removal performance of the local air conditioner 12 can be increased.

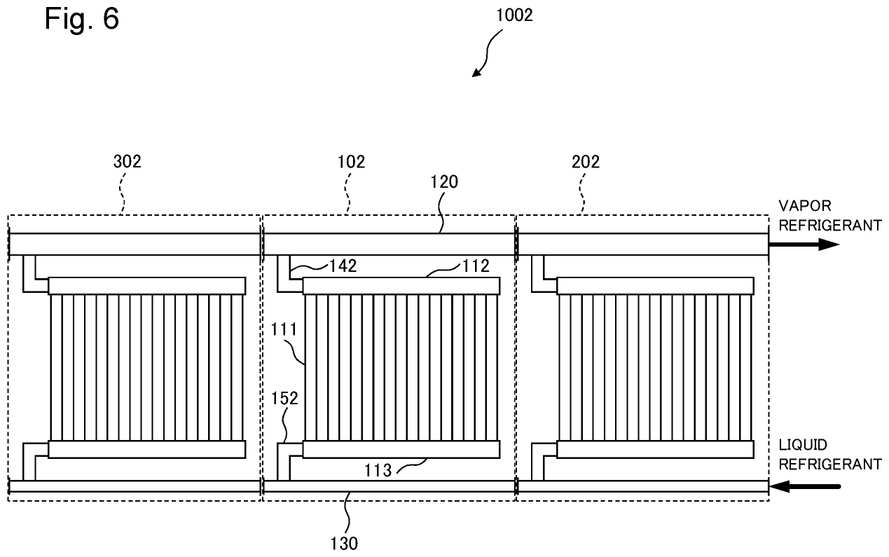

FIG. 6 illustrates a configuration of a local air conditioner system 1002 using a first local air conditioner 102, a second local air conditioner 202, and a third local air conditioner 302, each having the same configuration as the local air conditioner 12.

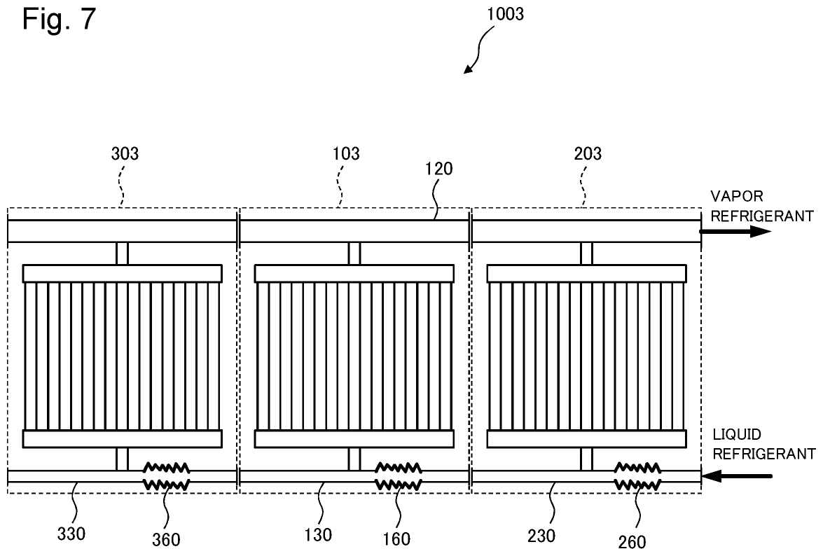

In the local air conditioner according to the present example embodiment, it may be configured in such a way that at least one of the first main flow pipe and the second main flow pipe includes expandable flexible piping (flexible pipe). FIG. 7 illustrates a configuration of a local air conditioner system 1003 including a first local air conditioner 103 having flexible piping 160 as a part of the second main flow pipe 130. Similarly to the first local air conditioner 103, a second local air conditioner 203 is configured to include flexible piping 260 as a part of a second main flow pipe 230, and a third local air conditioner 303 is configured to include flexible piping 360 as a part of a second main flow pipe 330.

By employing a configuration in which the pieces of flexible piping 160, 260, and 360 are inserted, deviation due to tolerance when a large number of local air conditioners are connected can be absorbed. Flow velocity of the liquid refrigerant is low due to a high density, and thus resistance due to the flexible piping (flexible pipe) is small. Therefore, it is preferable to employ the configuration of inserting the flexible piping (flexible pipe) into the second main flow pipe (liquid main flow pipe), however a configuration in which the flexible piping (flexible pipe) is inserted into the first main flow pipe (vapor main flow pipe) may be employed.

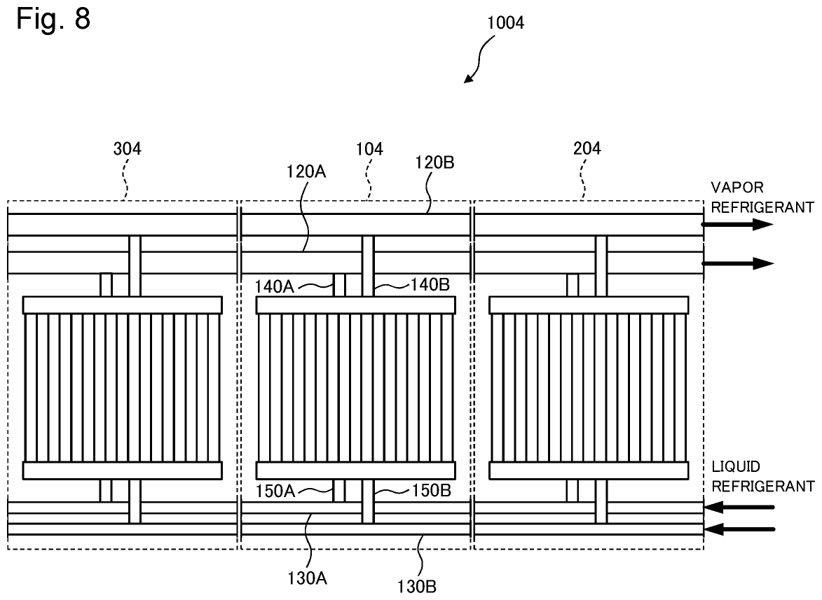

Further, the configuration of the local air conditioner can be a redundant configuration. FIG. 8 illustrates a configuration of a local air conditioner system 1004 using a first local air conditioner 104 having a double configuration. As illustrated in FIG. 8, the first local air conditioner 104 can be configured to include a plurality of first main flow pipes 120A and 120B, a plurality of second main flow pipes 130A and 130B, a plurality of first branch flow pipes 140A and 140B, and a plurality of second branch flow pipes 150A and 150B. A second local air conditioner 204 and a third local air conditioner 304 have the same configuration.

Even when a trouble such as a failure occurs in one piping system A, such a configuration enables continuing the operation of the local air conditioner by using the other piping system B. Herein, the piping system A is composed of the first main flow pipe 120A, the second main flow pipe 130A, the first branch flow pipe 140A, and the second branch flow pipe 150A, and the piping system B is composed of the first main flow pipe 120B, the second main flow pipe 130B, the first branch flow pipe 140B, and the second branch flow pipe 150B.

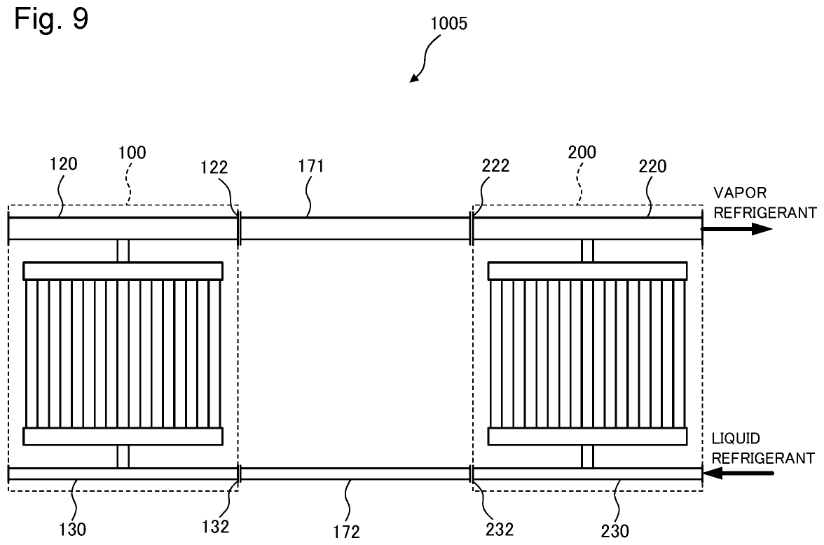

All of the local air conditioner systems 1000, 1001, 1002, 1003, and 1004 described above have a configuration in which the first local air conditioner and the second local air conditioner are directly connected by the first connection structure and the second connection structure. The configuration is not limited to this, and as a local air conditioner system 1005 illustrated in FIG. 9, it may be configured that the first connection structure 122 included in the first local air conditioner 100 and the first connection structure 222 included in the second local air conditioner 200 are connected via a first connection pipe 171. Similarly, it can be configured that the second connection structure 132 included in the first local air conditioner 100 and the second connection structure 232 included in the second local air conditioner 200 are connected via a second connection pipe 172.

Even when the server racks being cooling targets are not arranged adjacently in a server room, such a configuration enables installing only the required number of local air conditioners. Therefore, an introduction cost of the local air conditioner system can be suppressed.

Next, a method for manufacturing the local air conditioner system according to the present example embodiment will be described.

In the method for manufacturing the local air conditioner system according to the present example embodiment, first, a first local air conditioner is formed. Herein, the first local air conditioner includes a first heat exchanger, a first main flow pipe, a second main flow pipe, a first branch flow pipe that connects the first heat exchanger and the first main flow pipe, and a second branch flow pipe that connects the first heat exchanger and the second main flow pipe. The first main flow pipe includes a first connection structure on each of both end portions, and the second main flow pipe includes a second connection structure on each of both end portions.

Similarly, a second local air conditioner is formed. Herein, the second local air conditioner includes a second heat exchanger, a third main flow pipe, a fourth main flow pipe, a third branch flow pipe that connects the second heat exchanger and the third main flow pipe, and a fourth branch flow pipe that connects the second heat exchanger and the fourth main flow pipe. The third main flow pipe includes a third connection structure on each of both end portions, and the fourth main flow pipe includes a fourth connection structure on each of both end portions.

Then, the first connection structure and the third connection structure are connected, and the second connection structure and the fourth connection structure are connected.

In this way, the method for manufacturing the local air conditioner system according to the present example embodiment is able to connect, when an additional local air conditioner is installed, the local air conditioners by using the first connection structure and the third connection structure, and the second connection structure and the fourth connection structure. Therefore, there is no need to process metallic piping constituting the first main flow pipe, the second main flow pipe, the third main flow pipe, and the fourth main flow pipe.

In other words, the method for manufacturing the local air conditioner system according to the present example embodiment is able to easily install an additional local air conditioner in the local air conditioner system including a plurality of local air conditioners.

Note that connecting the first connection structure and the third connection structure described above can include connecting the first connection structure and the third connection structure via the first connection pipe.

Similarly, connecting the second connection structure and the fourth connection structure described above can include connecting the second connection structure and the fourth connection structure via the second connection pipe. Even when the server racks being cooling targets are not arranged adjacently in a server room, such a configuration enables installing only the required number of local air conditioners. Therefore, the introduction cost of the local air conditioner system can be suppressed.

### Second Example Embodiment

Next, a second example embodiment of the present invention will be described. A local air conditioner and a local air conditioner system according to the present example embodiment are configured to insert a valve into piping. Other configurations are similar to the local air conditioner and the local air conditioner system according to the first example embodiment, and thus the description thereof will be omitted.

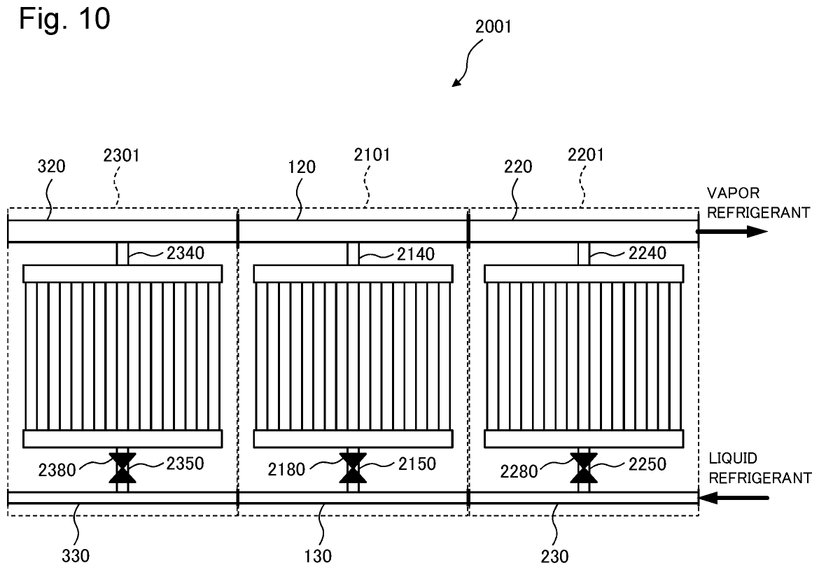

FIG. 10 schematically illustrates a configuration of a local air conditioner system 2001 including the local air conditioner according to the present example embodiment.

In a first local air conditioner 2101 according to the present example embodiment, it is configured that at least one of a first branch flow pipe 2140 and a second branch flow pipe 2150 includes a branch flow pipe valve. FIG. 10 illustrates a configuration in which the second branch flow pipe 2150 includes a branch flow pipe valve 2180. Similarly, a second local air conditioner 2201 has a configuration in which a second branch flow pipe 2250 includes a branch flow pipe valve 2280, and a third local air conditioner 2301 has a configuration in which a second branch flow pipe 2350 includes a branch flow pipe valve 2380.

A refrigerant flow rate can be controlled by the branch flow pipe valves 2180, 2280, and 2380, thereby enabling supply of a refrigerant amount depending on a received heat amount to the heat exchanger. As a result, heat removal can be performed more efficiently. Note that the branch flow pipe valves 2180, 2280, and 2380 may be manual valves or electric control valves.

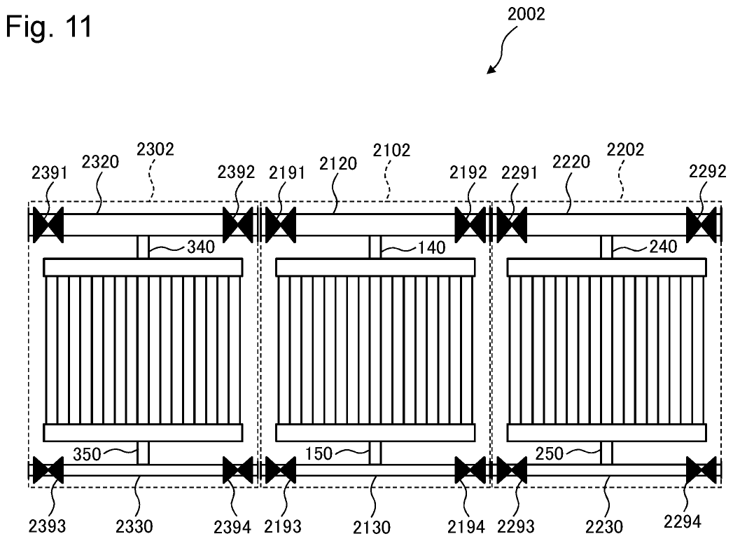

FIG. 11 illustrates another configuration of the local air conditioner system including the local air conditioner according to the present example embodiment. As illustrated in FIG. 11, in a first local air conditioner 2102 included in a local air conditioner system 2002 according to the present example embodiment, it is configured that at least one of a first main flow pipe 2120 and a second main flow pipe 2130 include the main flow pipe valve. FIG. 11 illustrates a configuration in which the first main flow pipe 2120 includes main flow pipe valves 2191 and 2192, and the second main flow pipe 2130 includes main flow pipe valves 2193 and 2194. As illustrated in FIG. 11, it can be configured in such a way that each main flow pipe valve is arranged at both ends of the first main flow pipe 2120 and at both ends of the second main flow pipe 2130.

According to the first local air conditioner 2102 according to the present example embodiment, when the first local air conditioner 2102 is attached to and detached from the local air conditioner system, it is possible to prevent air from being mixed into the piping by closing the main flow pipe valves 2191, 2192, 2193, and 2194.

Similarly, a second local air conditioner 2202 can be configured in such a way that a first main flow pipe 2220 includes main flow pipe valves 2291 and 2292, and a second main flow pipe 2230 includes main flow pipe valves 2293 and 2294. Further, a third local air conditioner 2302 can be configured in such a way that a first main flow pipe 2320 includes main flow pipe valves 2391 and 2392, and a second main flow pipe 2330 includes main flow pipe valves 2393 and 2394.

Similarly to the case according to the first example embodiment, the local air conditioner and the local air conditioner systems 2001 and 2002 including the local air conditioner according to the present example embodiment also enable installing an additional local air conditioner easily in the local air conditioner system including a plurality of local air conditioners.

Further, it can be configured that the configurations of the local air conditioners according to the above-described example embodiments are combined, and a similar advantageous effect can be acquired by the local air conditioner having such a configuration.

The whole or part of the example embodiments disclosed above can be described as, but not limited to, the following supplementary notes.

(Supplementary Note 1)

A local air conditioner including: a heat exchanger; a first main flow pipe; a second main flow pipe; a first branch flow pipe that connects the heat exchanger and the first main flow pipe; and a second branch flow pipe that connects the heat exchanger and the second main flow pipe, wherein the first main flow pipe includes a first connection structure on each of both end portions, and the second main flow pipe includes a second connection structure on each of both end portions.

(Supplementary Note 2)

The local air conditioner according to supplementary note 1, wherein the heat exchanger includes a heat exchange unit, a first header unit to be connected to the heat exchange unit, and a second header unit to be connected to the heat exchange unit, wherein the first header unit is located on one side and the second header unit is located on another side across the heat exchange unit, the first branch flow pipe is connected to the first header unit, and the second branch flow pipe is connected to the second header unit.

(Supplementary Note 3)

The local air conditioner according to supplementary note 2, wherein the first branch flow pipe is connected to the first header unit at a center of the first header unit, and the second branch flow pipe is connected to the second header unit at a center of the second header unit.

(Supplementary Note 4)

The local air conditioner according to supplementary note 2, wherein the first branch flow pipe is connected to the first header unit at a first end portion of the first header unit, the second branch flow pipe is connected to the second header unit at a second end portion of the second header unit, and the first end portion and the second end portion are located on a same side of a side surface of the heat exchange unit.

(Supplementary Note 5)

The local air conditioner according to supplementary note 2, wherein the first branch flow pipe is connected to the first header unit at a first end portion of the first header unit, the second branch flow pipe is connected to the second header unit at a second end portion of the second header unit, and the first end portion and the second end portion are located on different sides of side surfaces of the heat exchange unit.

(Supplementary Note 6)

The local air conditioner according to any one of supplementary notes 1 to 5, wherein at least one of the first main flow pipe and the second main flow pipe includes expandable flexible piping.

(Supplementary Note 7)

The local air conditioner according to any one of supplementary notes 1 to 6, wherein at least one of the first branch flow pipe and the second branch flow pipe includes a branch flow pipe valve.

(Supplementary Note 8)

The local air conditioner according to any one of supplementary notes 1 to 7, wherein at least one of the first main flow pipe and the second main flow pipe includes a main flow pipe valve.

(Supplementary Note 9)

A local air conditioner system including: a first local air conditioner being the local air conditioner according to any one of supplementary notes 1 to 8; and a second local air conditioner being the local air conditioner according to any one of supplementary notes 1 to 8, wherein the first connection structure included in the first local air conditioner and the first connection structure included in the second local air conditioner are connected, and the second connection structure included in the first local air conditioner and the second connection structure included in the second local air conditioner are connected.

(Supplementary Note 10)

A method for manufacturing a local air conditioner system comprising: forming a first local air conditioner; the first local air conditioner includes a first heat exchanger, a first main flow pipe, a second main flow pipe, a first branch flow pipe that connects the first heat exchanger and the first main flow pipe, and a second branch flow pipe that connects the first heat exchanger and the second main flow pipe, wherein the first main flow pipe includes a first connection structure on each of both end portions, the second main flow pipe includes a second connection structure on each of both end portions, forming a second local air conditioner; the second local air conditioner includes a second heat exchanger, a third main flow pipe, a fourth main flow pipe, a third branch flow pipe that connects the second heat exchanger and the third main flow pipe, and a fourth branch flow pipe that connects the second heat exchanger and the fourth main flow pipe, wherein the third main flow pipe includes a third connection structure on each of both end portions, the fourth main flow pipe includes a fourth connection structure on each of both end portions; connecting the first connection structure and the third connection structure; and connecting the second connection structure and the fourth connection structure.

(Supplementary Note 11)

The local air conditioner according to any one of supplementary notes 1 to 8 including: a plurality of the first main flow pipes; a plurality of the second main flow pipes; a plurality of the first branch flow pipes; and a plurality of the second branch flow pipes.

(Supplementary Note 12)

The local air conditioner according to any one of supplementary notes 1 to 8 and 11, wherein the first connection structure and the second connection structure each include one of a sanitary flange and a normal flange.

(Supplementary Note 13)

The local air conditioner system according to supplementary note 9, wherein the first connection structure included in the first local air conditioner and the first connection structure included in the second local air conditioner are connected via a first connection pipe, and the second connection structure included in the first local air conditioner and the second connection structure included in the second local air conditioner are connected via a second connection pipe.

(Supplementary Note 14)

The local air conditioner system according to supplementary note 9 or 13, wherein the first connection structure and the second connection structure each include any one of a sanitary flange and a normal flange.

(Supplementary Note 15)

The method for manufacturing the local air conditioner system according to supplementary note 10, wherein the connecting the first connection structure and the third connection structure includes connecting the first connection structure and the third connection structure via a first connection pipe, and the connecting the second connection structure and the fourth connection structure includes connecting the second connection structure and the fourth connection structure via a second connection pipe.

(Supplementary Note 16)

The method for manufacturing the local air conditioner system according to supplementary note 10 or 15, wherein the first connection structure and the second connection structure each include any one of a sanitary flange and a normal flange.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2017-245655, filed on Dec. 22, 2017, the disclosure of which is incorporated herein in its entirety by reference.

### REFERENCE SIGNS LIST

10, 11, 12 Local air conditioner
100, 101, 102, 103, 104, 2101, 2102 First local air conditioner
110, 310 Heat exchanger
111, 311 Heat exchange unit
112, 312 First header unit
113, 313 Second header unit
120, 120A, 120B, 220, 320, 2120, 2220, 2320 First main flow pipe
121, 122, 222, 322 First connection structure
130, 130A, 130B, 230, 330, 2130, 2230, 2330 Second main flow pipe
131, 132, 232, 332 Second connection structure
140, 140A, 140B, 141, 142, 340, 2140 First branch flow pipe
150, 150A, 150B, 151, 152, 350, 2150, 2250, 2350 Second branch flow pipe
160, 260, 360 Flexible piping
171 First connection pipe
172 Second connection pipe
200, 201, 202, 203, 204, 2201, 2202 Second local air conditioner
300, 301, 302, 303, 304, 2301, 2302 Third local air conditioner
1000, 1001, 1002, 1003, 1004, 1005, 2001, 2002 Local air conditioner system
2180, 2280, 2380 Branch flow pipe valve
2191, 2192, 2193, 2194, 2291, 2292, 2293, 2294, 2391, 2392, 2393, 2394 Main flow pipe valve

What is claimed is:

1. A local air conditioner comprising:
a heat exchanger;
a first main flow pipe;
a second main flow pipe;
a first branch flow pipe that connects the heat exchanger and the first main flow pipe; and
a second branch flow pipe that connects the heat exchanger and the second main flow pipe, wherein
the first main flow pipe includes a first connection structure on each of both end portions, and
the second main flow pipe includes a second connection structure on each of both end portions.

2. The local air conditioner according to claim 1, wherein
the heat exchanger includes
a heat exchange unit,
a first header unit to be connected to the heat exchange unit, and
a second header unit to be connected to the heat exchange unit, wherein
the first header unit is located on one side and the second header unit is located on another side across the heat exchange unit,
the first branch flow pipe is connected to the first header unit, and
the second branch flow pipe is connected to the second header unit.

3. The local air conditioner according to claim 2, wherein
the first branch flow pipe is connected to the first header unit at a center of the first header unit, and
the second branch flow pipe is connected to the second header unit at a center of the second header unit.

4. The local air conditioner according to claim 2, wherein
the first branch flow pipe is connected to the first header unit at a first end portion of the first header unit,
the second branch flow pipe is connected to the second header unit at a second end portion of the second header unit, and
the first end portion and the second end portion are located on a same side of a side surface of the heat exchange unit.

5. The local air conditioner according to claim 2, wherein
the first branch flow pipe is connected to the first header unit at a first end portion of the first header unit,
the second branch flow pipe is connected to the second header unit at a second end portion of the second header unit, and
the first end portion and the second end portion are located on different sides of side surfaces of the heat exchange unit.

6. The local air conditioner according to claim 1, wherein
at least one of the first main flow pipe and the second main flow pipe includes expandable flexible piping.

7. The local air conditioner according to claim 1, wherein
at least one of the first branch flow pipe and the second branch flow pipe includes a branch flow pipe valve.

8. The local air conditioner according to claim 1, wherein
at least one of the first main flow pipe and the second main flow pipe includes a main flow pipe valve.

9. A local air conditioner system comprising:
a first local air conditioner configured in accordance with a local air conditioner; and
a second local air conditioner configured in accordance with the local air conditioner, wherein
the local air conditioner includes
a heat exchanger, a first main flow pipe, a second main flow pipe,
a first branch flow pipe that connects the heat exchanger and the first main flow pipe, and a second branch flow pipe that connects the heat exchanger and the second main flow pipe, wherein
the first main flow pipe includes a first connection structure on each of both end portions, and
the second main flow pipe includes a second connection structure on each of both end portions,
the first connection structure included in the first local air conditioner and the first connection structure included in the second local air conditioner are connected, and
the second connection structure included in the first local air conditioner and the second connection structure included in the second local air conditioner are connected.

10. A method for manufacturing a local air conditioner system comprising:
forming a first local air conditioner;
the first local air conditioner includes a first heat exchanger, a first main flow pipe, a second main flow pipe,
a first branch flow pipe that connects the first heat exchanger and the first main flow pipe, and
a second branch flow pipe that connects the first heat exchanger and the second main flow pipe, wherein
the first main flow pipe includes a first connection structure on each of both end portions,
the second main flow pipe includes a second connection structure on each of both end portions,
forming a second local air conditioner;
the second local air conditioner includes a second heat exchanger, a third main flow pipe, a fourth main flow pipe,
a third branch flow pipe that connects the second heat exchanger and the third main flow pipe, and
a fourth branch flow pipe that connects the second heat exchanger and the fourth main flow pipe, wherein
the third main flow pipe includes a third connection structure on each of both end portions,
the fourth main flow pipe includes a fourth connection structure on each of both end portions;
connecting the first connection structure and the third connection structure; and
connecting the second connection structure and the fourth connection structure.

11. The local air conditioner according to claim 1 further comprising:
a plurality of the first main flow pipes;
a plurality of the second main flow pipes;
a plurality of the first branch flow pipes; and
a plurality of the second branch flow pipes.

12. The local air conditioner according to claim 1, wherein
the first connection structure and the second connection structure each include one of a sanitary flange and a normal flange.

13. The local air conditioner system according to claim 9, wherein
the first connection structure included in the first local air conditioner and the first connection structure included in the second local air conditioner are connected via a first connection pipe, and
the second connection structure included in the first local air conditioner and the second connection structure included in the second local air conditioner are connected via a second connection pipe.

14. The local air conditioner system according to claim 9, wherein
the first connection structure and the second connection structure each include any one of a sanitary flange and a normal flange.

15. The method for manufacturing the local air conditioner system according to claim 10, wherein
the connecting the first connection structure and the third connection structure includes connecting the first connection structure and the third connection structure via a first connection pipe, and
the connecting the second connection structure and the fourth connection structure includes connecting the second connection structure and the fourth connection structure via a second connection pipe.

16. The method for manufacturing the local air conditioner system according to claim 10, wherein
the first connection structure and the second connection structure each include any one of a sanitary flange and a normal flange.

17. The local air conditioner according to claim 2, wherein
at least one of the first main flow pipe and the second main flow pipe includes expandable flexible piping.

18. The local air conditioner according to claim 3, wherein
at least one of the first main flow pipe and the second main flow pipe includes expandable flexible piping.

19. The local air conditioner according to claim 4, wherein
at least one of the first main flow pipe and the second main flow pipe includes expandable flexible piping.

20. The local air conditioner according to claim 5, wherein
at least one of the first main flow pipe and the second main flow pipe includes expandable flexible piping.
